(19) United States
(12) Patent Application Publication
(10) Pub. No.: US 2009/0278561 A1
(43) Pub. Date: Nov. 12, 2009

(54) PROBE CARD HAVING REDISTRIBUTED WIRING PROBE NEEDLE STRUCTURE AND PROBE CARD MODULE USING THE SAME

(76) Inventors: Cha-jea Jo, Bucheon-si (KR); Tae-gyeong Chung, Suwon-si (KR); Hoon-jung Kim, Yongin-si (KR); Nam-seog Kim, Yongin-si (KR); Chang-seong Jeon, Suwon-si (KR)

Correspondence Address: F. CHAU & ASSOCIATES, LLC, 130 WOODBURY ROAD, WOODBURY, NY, 11797, US

(21) Appl. No.: 12/330,146

(22) Filed: Dec. 8, 2008

(30) Foreign Application Priority Data
May 8, 2008 (KR) 10-2008-42997

(51) Int. Cl. G01R 1/073

(52) U.S. Cl. 324/761

(57) ABSTRACT

The probe card is comprised of a probe card wafer, a plurality of through via electrodes penetrating the probe card wafer; and a plurality of redistributed wiring probe needle structures, each being connected to the through via electrodes protruding from a surface of the probe card wafer.

### CROSS-REFERENCE TO RELATED PATENT APPLICATIONS

This application claims priority to Korean Patent Application No, 10-2008-0042997, filed on May 8, 2008, in the Korean Intellectual Property Office, the disclosure of which is incorporated by reference in their entirety.

### BACKGROUND OF THE INVENTION

1. Technical Field

The present disclosure relates to a probe card and a probe card module using the same, and more particularly, to a probe card having a redistributed wiring probe needle structure, and a probe card module using the probe card.

2. Discussion of the Related Art

In general, during a semiconductor device manufacturing process, unit chips formed on a wafer are electrically tested. The electrical test of a wafer is referred to as an electronic die sort (EDS) test.

The EDS test is to electrically test functions of the unit chips on a wafer. Chips that pass the EDS test are manufactured into semiconductor packages in an assembly process. Chips determined to be defective in the EDS test are scrap disposed in early stage so as to avoid unnecessary costs in the assembly process.

Typically, the EDS test is performed using a tester and a probe station. The tester is an automatic test equipment (ATE) for testing electrical functions of the unit chip by applying an electrical signal such as a voltage, current, or clock to the unit chip on the wafer. The tester includes a probe card having a plurality of probe needles for applying electrical signals to the wafer. The probe station is an automatic transfer and alignment equipment for moving the wafer to accurately connect the unit chips on the wafer to the tester via the probe needles.

However, to apply various electrical signals, a general probe card includes a multilayer wiring substrate (for example, a multilayer ceramic substrate formed of a printed circuit board (PCB) substrate) and a cantilever type spring probe needle installed on the multilayer wiring substrate. Since such a probe card is manufactured using a micro-electro-mechanical systems (MEMS) technology, the manufacturing and testing processes may be extremely time consuming and costly.

Accordingly, there exists a need for a probe card which has a shortened manufacturing period, a low manufacturing cost, and a reduced test time.

### SUMMARY OF THE INVENTION

According to an embodiment of the present invention, there is provided a probe card comprising a probe card wafer, a plurality of through via electrodes penetrating the probe card wafer; and a plurality of redistributed wiring probe needle structures, each being connected to one of the through via electrodes and having a twisted cage shape protruding from a surface of the probe card wafer.

Each of the redistributed wiring probe needle structures may be comprised of a metal ring connected to each of the through via electrodes, a plurality of bars separated from one another and connected to the metal ring, and a probe needle supportingly connected to the bars, where in each of the bars is dimensioned and shaped to connect between the metal ring and the probe needle. The diameter of the metal ring is greater than that of the probe needle. A buffer member may fill a space between the bars of each of the redistributed wiring probe needle structures. Multilayered wiring layers may be formed in the probe card wafer and electrically connected to the through via electrodes. The redistributed wring probe needle structures may be formed on a surface of the probe card wafer and connected to the through via electrodes, and connection terminals may be formed on the other surface of the probe card wafer and connected to a wiring substrate.

The probe card wafer may be comprised of a first probe card wafer where a plurality of first through via electrodes and the redistributed wring probe needle structures are formed, and a second probe card wafer where a plurality of second through via electrodes electrically connected to the first through via electrodes and the redistributed wring probe needle structures on the first probe card wafer, and connection terminals connected to the second through via electrodes and the wiring substrate, are formed. The first probe card wafer may be combined to the second probe card wafer.

According to another embodiment of the present invention, there is a probe card module comprising a wiring substrate connected to a tester; and a probe card electrically connected to the wiring substrate and testing a unit chip of a test wafer. The probe card may be comprised of a probe card wafer corresponding to the test wafer; a plurality of through via electrodes penetrating the probe card wafer; and a plurality of redistributed wiring probe needle structures, each being connected to each of the through via electrodes protruding from the probe card wafer.

Each of the redistributed wiring probe needle structures may comprise: a metal ring connected to each of the through via electrodes; a plurality of bars separated from one another; and a probe needle supportingly connected to the bars; wherein each of the bars is dimensioned and shaped to connect between the metal ring and the probe needle. Each of the redistributed wiring probe needle structures may comprise a plurality of bars connected to the metal ring and, when the probe needle electrically contacts a pad of the unit chip of the test wafer, the probe needle rotates. The redistributed wring probe needle structures are formed on a surface of the probe card wafer and connected to the through via electrodes, and connection terminals are formed on the other surface of the probe card wafer and connected to a wiring substrate.

The probe card wafer may comprise: a first probe card wafer where a plurality of first through via electrodes and the redistributed wring probe needle structures are formed; and a second probe card wafer where a plurality of second through via electrodes electrically connected to the first through via electrodes and the redistributed wring probe needle structures on the first probe card wafer, and connection terminals connected to the second through via electrodes and the wiring substrate, are formed. A buffer member may fill the inside of each of the redistributed wring probe needle structures.

According to another embodiment of the present invention, there is a probe card module comprising a wiring substrate connected to a tester, a guide member installed on a surface of the wiring substrate and having an open central portion, and a probe card electrically installed by being supported by the guide member electrically connected to the wiring substrate, and testing a unit chip of a test wafer.

The probe card may be comprised of a probe card wafer corresponding to the test wafer, a plurality of connection terminals installed on a surface of the probe card wafer and connected to the wiring substrate via a plurality of microsprings, a plurality of through via electrodes penetrating the probe card wafer, and a plurality of redistributed wiring probe needle structures, each being connected to each of the through via electrodes protruding from the probe card wafer. Each of the redistributed wiring probe needle structures may be rotated when each of the redistributed wiring probe needle structures electrically contacts a pad of a unit chip of the test wafer.

### BRIEF DESCRIPTION OF THE DRAWINGS

Embodiments of the present invention will become more apparent by describing in detail exemplary embodiments thereof with reference to the attached drawings in which:

FIG. 1 is a cross-sectional view of a probe card module including a probe card, according to an embodiment of the present invention;

FIG. 2 is a cross-sectional view of a probe card module including a probe card, according to another embodiment of the present invention; FIG. 3 is a cross-sectional view of a probe card module including a probe card for the comparison with the probe card modules of FIGS. 1 and 2, according to an embodiment of the present invention;

FIGS. 4-7 are cross-sectional views of the probe card according to an embodiment of the present invention;

FIGS. 8-11 illustrate a redistributed wiring probe needle structure according to an embodiment of the present invention;

FIGS. 12-14 illustrate a redistributed wiring probe needle structure filled with a buffer member according to another embodiment of the present invention; and

FIGS. 15-17 are cross-sectional views of a redistributed wiring probe needle structure according to an embodiment of the present invention.

### DESCRIPTION OF EMBODIMENTS

Embodiments of the present invention will be described in detail by explaining exemplary embodiments of the invention with reference to the attached drawings. This invention may, however, be embodied in many different forms and should not be constructed as limited to the embodiment set forth herein. The same reference numerals in the drawings may refer to same or similar elements.

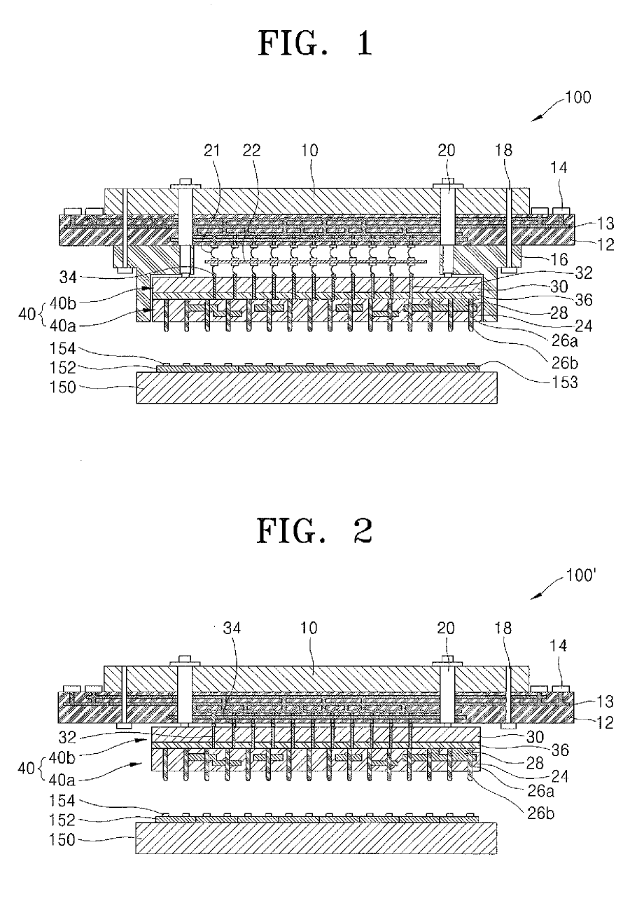

FIG. 1 is a cross-sectional view of a probe card module 100 including a probe card, according to an embodiment of the present invention.

Referring to FIG. 1, the probe card module 100 according to an embodiment of the present invention includes a body 10 mechanically connected to a tester (not shown) and a wiring substrate 12 supported by a plurality of columns 18 and 20 in the body 10. A wiring layer 13 is formed in the wiring substrate 12. A plurality of connection terminals 14 that are electrically connected to the tester are formed on a surface of the wiring substrate 12. The wiring substrate 12 is formed of a printed circuit board substrate. A guide member 16 having an open central portion is installed on the other surface of the wiring substrate 12 by means of the columns 18 and 20. A plurality of microsprings 21 are connected to the wiring layer 13 on the rear surface, i.e., the other surface of the wiring substrate 12 surrounded by the guide member 16. The microsprings 21 are supported by a microspring interposer 22.

The microsprings 21 connected to the wiring substrate 12 are connected to a wafer probe card 40. The probe card 40 is supported and guided by the guide member 16 and the wiring substrate 12. The probe card 40 is electrically connected to the wiring substrate 12 via the microsprings 21. The probe card 40 contacts a pad 154 of each of a plurality of unit chips 153 of a test wafer 152 to thereby determine good or bad unit chips 153. The test wafer 152 is accommodated on a probe station 150. The pad 154 is formed of an aluminum layer.

In the present embodiment, the probe card module 100 includes various elements such as the wiring substrate 12, the guide member 16, and the probe card 40. However, the probe card module 100 may be referred to as a probe card.

The probe card 40 of the present embodiment includes a pair of first and second probe card wafers 24 and 30 in a wafer scale corresponding to the test wafer 152. The test wafer 152 and the first and second probe card wafers 24 and 30 are formed of a silicon wafer. A plurality of connection terminals 34 are installed on a surface of each of the first and second probe card wafers 24 and 30 to be connected to the wiring substrate 12 via the microsprings 21. A plurality of first and second through via electrodes 26a and 32 are respectively installed in the first and second probe card wafers 24 and 30. The first and second through via electrodes 26a and 32 may be formed using a wafer processing process (fabrication process). Multilayered wiring layers 28 are formed in the first probe card wafer 24. The multilayered wiring layers 28 are electrically connected to the first and second through via electrodes 26a and 32.

The probe card 40 includes a redistributed wiring probe needle structure 26b having a twisted cage, which are connected to the first and second through via electrodes 26a and 32 and protrudes downwardly (perpendicularly) from the first and second probe card wafers 24 and 30. The redistributed wiring probe needle structure 26b, may be formed using a redistributed wiring process that is used for wafer processing (fabrication process). The redistributed wiring probe needle structure 26b rotates when the probe card 40 electrically contacts the pad 154 of each unit chip of the test wafer 152. Then, the redistributed wiring probe needle structure 26b contacts the pad 154 with friction to remove foreign or impurity materials on the pad 154 so that contact reliability between the redistributed wiring probe needle structure 26b and the pad 154 can be greatly improved.

The probe card 40 may include a first probe card 40a and a second probe card 40b coupled to the first probe card 40a. The probe card 40 may be formed of a single probe card wafer. The first probe card 40a includes the first through via electrodes 26a and the redistributed wiring probe needle structure 26b installed in the first probe card wafer 24.

The second probe card 40b includes the second probe card wafer 30 coupled to the first probe card wafer 24. The second probe card 40b also includes the second through via electrodes 32 installed in the second probe card wafer 30 and electrically connected to the through via electrodes 26a and the redistributed wiring probe needle structure 26b, and the connection terminals 34 connected to the second through via electrodes 32 and the wiring substrate 12. The first probe card wafer 24 and the second probe card wafer 30 may be combined by using a combination layer or adhesive layer 36.

FIG. 2 is a cross-sectional view of a probe card module 100′ including a probe card, according to another embodiment of the present invention.

Referring to FIG. 2, the structure of the probe card module 100′ is the same as that of the probe card module 100 of FIG. 1, except for attaching the probe card 40 to the wiring substrate 12 without using the guide member 16 and the microsprings 21. That is, in the probe card module 100′ of the present embodiment, the connection terminals 34 formed on the rear surface of the wiring substrate 12 and the probe card 40 of a wafer scale are directly connected to each other. Thus, the wiring substrate 12 and the probe card 40 can be easily connected.

FIG, 3 is a cross-sectional view of a probe card module 200 including a probe card for the comparison with the probe card modules of FIGS. 1 and 2.

The structure of the probe card module 200 of FIG. 3 is the same as that of the probe card module 100 of FIG. 1, except for the structure of a probe card 210. The probe card 210 of FIG. 3 is connected to the wiring substrate 12 via the microsprings 21. The probe card 210 includes a multilayered wiring substrate 202 having a multilayered wiring layer 206, a guide plate 204 connected to the multilayered wiring substrate 202, and a probe needle 208 of a spring type installed in the guide plate 204. The multilayered wiring substrate 202 is formed of a PCB substrate.

In the probe card 210 of FIG. 3 the multilayered wiring substrate 202 and the probe needle 208 are manufactured using a microelectromechanical system (MEMS) technology.

The probe card 40 of FIGS. 1 and 2 of the present embodiment is formed of the probe card wafers 24 and 30 of a wafer scale instead of the multilayered wiring substrate 202 and the guide plate 204 of the comparative example. The probe card 40 of a wafer scale of FIGS. 1 and 2 uses a wafer level processing technique and a wafer level package technique, instead of the MEMS technology, so that a manufacturing period can be shortened and a manufacturing cost can be reduced. Also, the probe card 40 of a wafer scale of the present invention can probe (test) at once unit chips on a wafer so that a test time can be remarkably reduced.

The structure of a probe card of a wafer scale and a manufacturing method thereof will be described below.

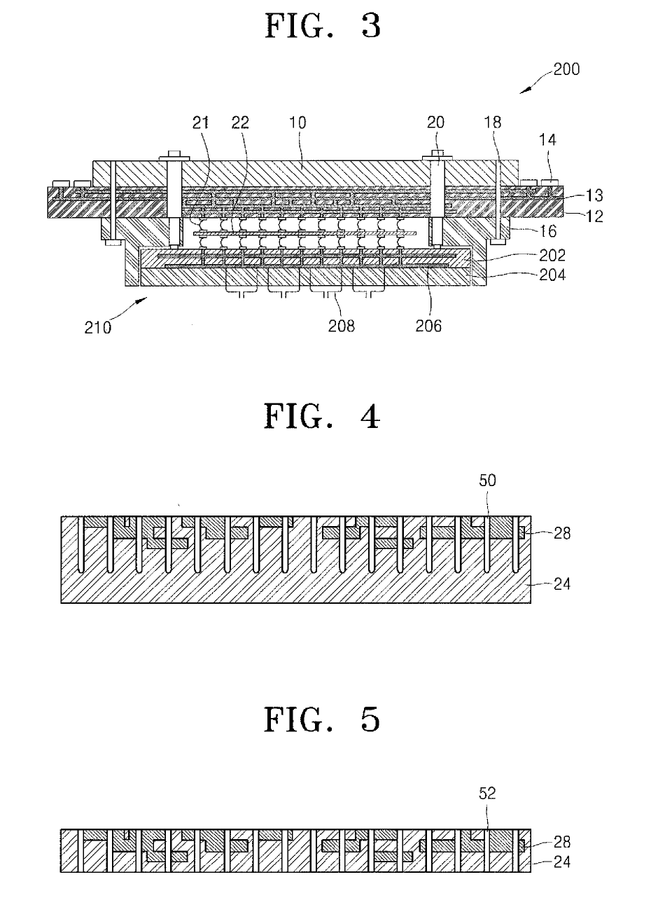

FIGS. 4-7 are cross-sectional views for explaining the structure and manufacturing method of the probe card according to an embodiment of the present invention.

Referring to FIGS. 4 and 5, to manufacture the probe card 40 of the present invention, the first probe card wafer 24 is prepared and the multilayered wiring layers 28 and a plurality of holes 50 are formed using the wafer-level processing technique. Then, as shown in FIG. 5, a surface of the first probe card wafer 24 is polished to form a plurality of through via holes 52. The polishing process of the first probe card wafer 24 may be performed using a chemical mechanical polishing process.

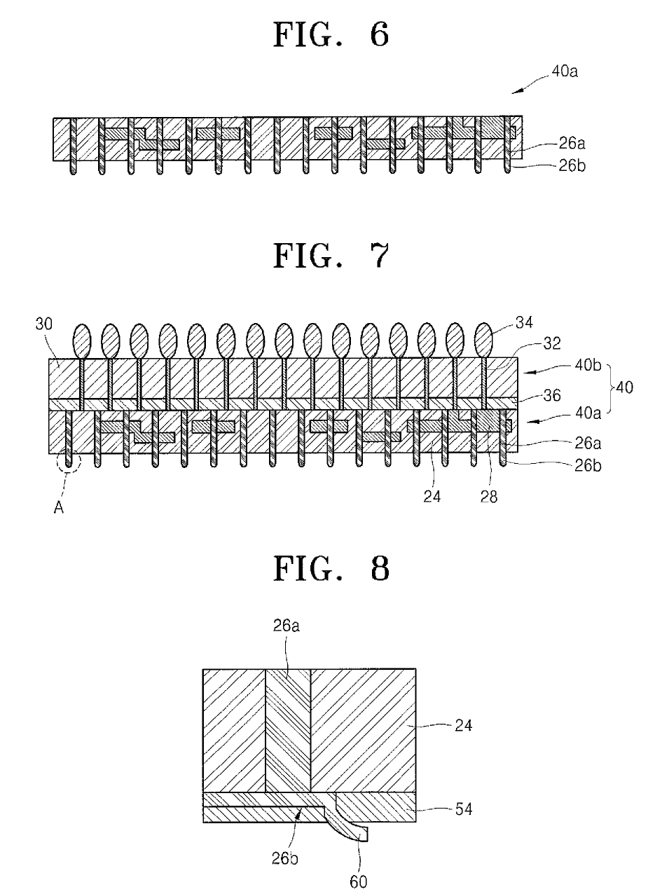

Referring to FIG. 6, a conductive layer is formed in each of the through via holes 52 so as to form the through via electrodes 26a. Then, the redistributed wiring probe needle structure 26b connected to the through via electrodes 26a and protruding from a surface of the first probe card wafer 24 is formed, thereby completing the first probe card 40a. The fabrication of redistributed wiring probe needle structure 26b will be described below in detail.

Referring to FIG. 7, the second probe card wafer 30 in which the second through via electrodes 32 are formed using the wafer-level processing technique is provided. In the probe card modules 100 and 100′, the second probe card wafer 30 is prepared to adjust the thickness of the probe card 40 in the guide member 16. The second probe card wafer 30 is coupled to the first probe card wafer 24 using the combination layer or adhesive layer 36.

Then, the second through via electrodes 32, electrically connected to the through via electrodes 26a and the redistributed wiring probe needle structure 26b, are formed in the second probe card wafer 30. The connection terminals 34, for example, solder balls, connecting to the wiring substrate 12, are formed on the second through via electrodes 32 of the second probe card wafer 30, using the wafer-level packaging technique, thereby completing the second probe card 40b.

Although in FIGS. 4-7 the probe card 40 is formed by using the first and second probe card wafers 24 and 30, the probe card 40 may be formed by using a single probe card wafer. The redistributed wiring probe needle structure 26b used for the probe card 40 will be described below in detail.

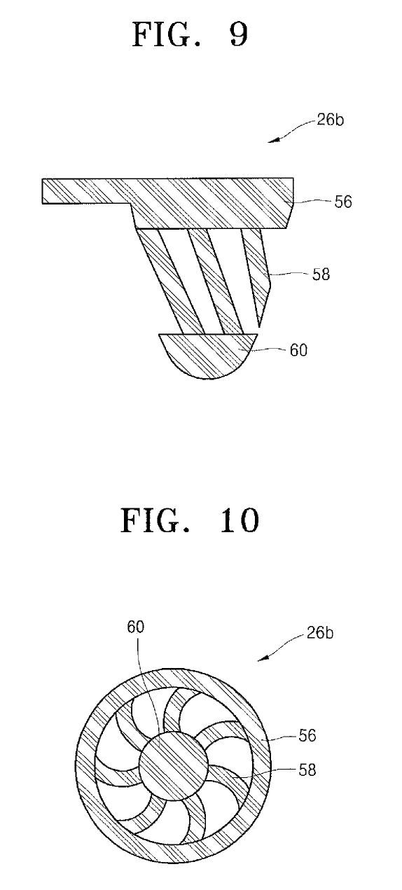

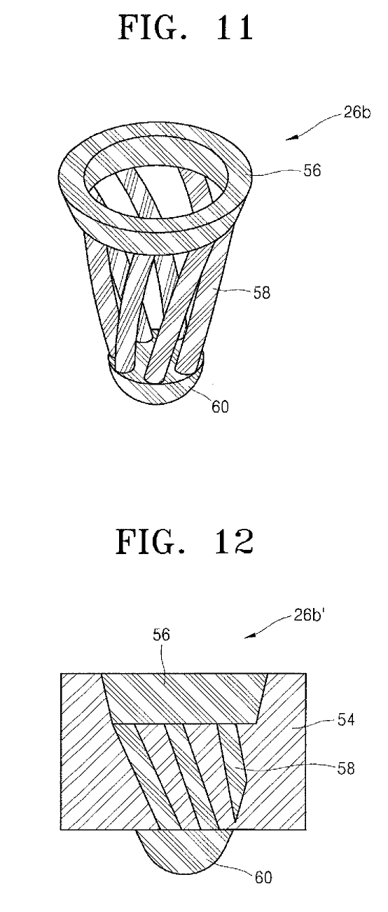

FIGS. 8-11 illustrate a redistributed wiring probe needle structure according to an embodiment of the present invention. FIG, 8 is a cross-sectional view of a portion A of FIG. 7. FIG. 9 is an enlarged cross-sectional view of the redistributed wiring probe needle structure 26b. FIG. 10 is an enlarged plan view of the redistributed wiring probe needle structure 26b. FIG. 11 is a perspective view of the redistributed wiring probe needle structure 26b.

As shown in FIG. 8, the through via electrodes 26a are installed in the first probe card wafer 24. The redistributed wiring probe needle structure 26b is installed at the through via electrodes 26a to protrude from a surface of the first probe card wafer 24. A buffer member 54 may be formed of a material exhibiting a superior elasticity, for example, a silicon material, around the redistributed wiring probe needle structure 26b, if necessary. Even when the buffer member 54 is formed, a probe needle 60 at a tip end of the redistributed wiring probe needle structure 26b protrudes externally.

As shown in FIGS. 9-11, the redistributed wiring probe needle structure 26b has a twisted cage shape. That is, the redistributed wiring probe needle structure 26b includes a metal ring 56 connected to each of the through via electrodes 26a, a plurality of bars 58 separated from one another and connected to the metal ring 56, and the probe needle 60 connected to and supporting the bars 58. Each of the bars is dimensioned and shaped to connect between the metal ring and the probe needle to form a cage shape.

In FIGS. 9-11, the buffer member 54 is not shown for the convenience of explanation. The diameter of the metal ring 56 is greater than that of the probe needle 60. The probe needle 60 may be a solid cylinder or hemispherical. Referring back to FIG. 1, when the redistributed wiring probe needle structure 26b having a twisted cage shape moves so that the probe needle 60 located at the tip end (lower end) of the redistributed wiring probe needle structure 26b contacts the pad 154 of each unit chip of the test wafer 152, the probe needle 60 can be mechanically rotated. Accordingly, the redistributed wiring probe needle structure 26b of the present invention causes friction with the pad 154 so that contact ability between the probe needle 60 and the pad 154 can be improved and reliability of test can be improved.

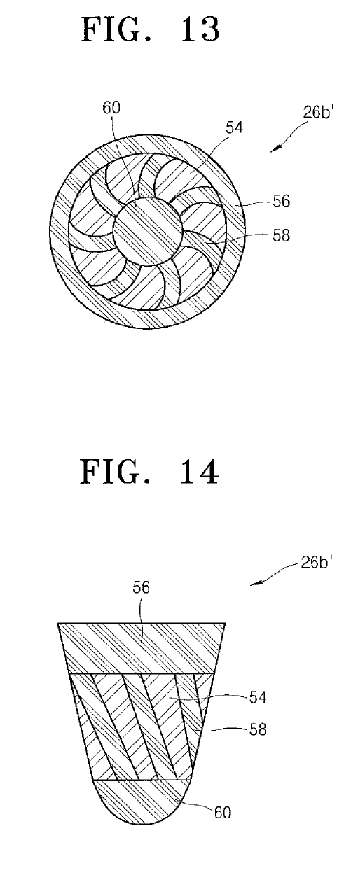

FIGS. 12-14 illustrate a redistributed wiring probe needle structure filled with a buffer member according to another embodiment of the present invention. FIGS. 12 and 14 are enlarged cross-sectional views of a redistributed wiring probe needle structure 26b′ according to another embodiment of the present invention. FIG. 13 is an enlarged plan view of the redistributed wiring probe needle structure 26b′ of FIG. 12.

The structure of the redistributed wiring probe needle structure 26b′ of FIGS. 12-14 is the same as that of the redistributed wiring probe needle structure 26b of FIGS. 9-11, except that the inside of the redistributed wiring probe needle structure 26b′ having a twisted cage is filled with the buffer member 54. That is, in the redistributed wiring probe needle structure 26b′ of FIGS. 12-14, the buffer member 54 fills a space between the bars 58 surrounding the metal ring 56 and the probe needle 60 protrudes externally. In other words, the redistributed wiring probe needle structure 26b′ of FIGS. 12-14 has the buffer member 54 inside which is stable to high temperature and exhibits a superior elasticity.

Referring back to FIG. 1, when the redistributed wiring probe needle structure 26b′ of FIGS. 12-14 moves so that the probe needle 60 located at the tip end (lower end) of the redistributed wiring probe needle structure 26b′ contacts the pad 154 of each unit chip of the test wafer 152, the probe needle 60 is rotated and mechanically stably contacts the pad 154. When the buffer member 54 is formed in the redistributed wiring probe needle structure 26b′, a test can be performed according to a temperature history from high temperature to low temperature so that durability of a probe card can be greatly improved.

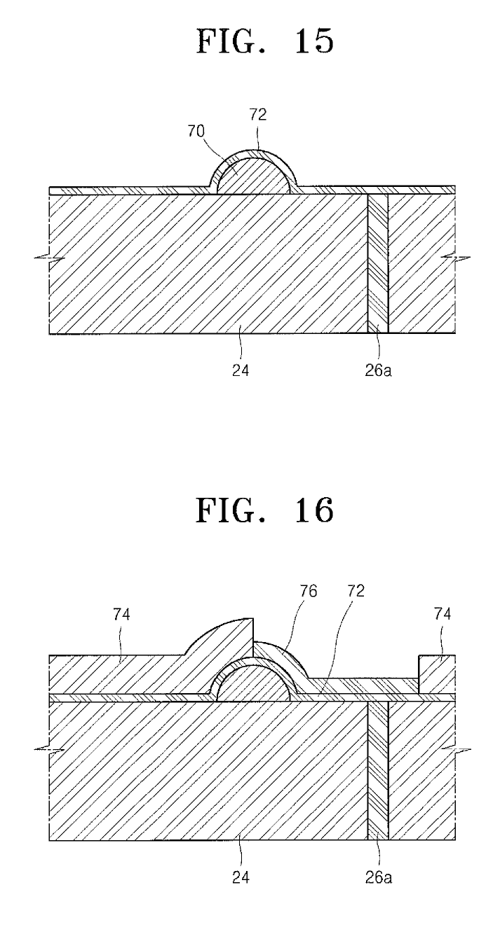

FIGS. 15-17 are cross-sectional views for explaining a method of manufacturing a redistributed wiring probe needle structure according to an embodiment of the present invention.

Referring to FIG. 15, a bump pattern 70 is formed on the first probe card wafer 24 where the through via electrodes 26a are formed. The bump pattern 70 is formed by forming a polymer pattern on the first probe card wafer 24 using the wafer processing technique and applying a heat treatment thereto. The bump pattern 70 may be formed by a variety of wafer processing processes. A seed metal layer 72 is formed on the bump pattern 70 and the first probe card wafer 24. The seed metal layer 72 is formed as a Ti, Cu, Au, or Ni layer using a vacuum deposition method.

Referring to FIG. 16, a photoresist pattern 74 is formed on the seed metal layer 72 to expose the upper portions of the through via electrodes 26a. The photoresist pattern 74 is formed using a photolithography process. The shape of the photoresist pattern 74, that is, the shape of the interior of the photoresist pattern 74, is formed to be the same as that shown in FIGS. 9-11. Next, a redistributed wiring layer 76 is formed by forming a metal pattern on the seed metal layer 72 in the photoresist pattern 74, using a plate method, for example, electroplating or electroless plating. The redistributed wiring layer 76 can be formed in other various methods, in addition to the plate method.

The redistributed wiring layer 76 may be formed as a conductive metal layer. The redistributed wiring layer 76 is formed of a base metal layer formed of a Ni based or Fe based alloy layer to maintain mechanical elasticity and a metal layer formed by depositing a copper layer or silver layer exhibiting a high conductivity on the base metal layer to evaluate an electrical characteristic. In addition, the redistributed wiring layer 76 is formed of the base metal layer and the metal layer and may further include a rigid gold layer suitable for an electrical contact structure on the outermost surface of the redistributed wiring probe needle structure 26b contacting the pad 154 of the test wafer 152.

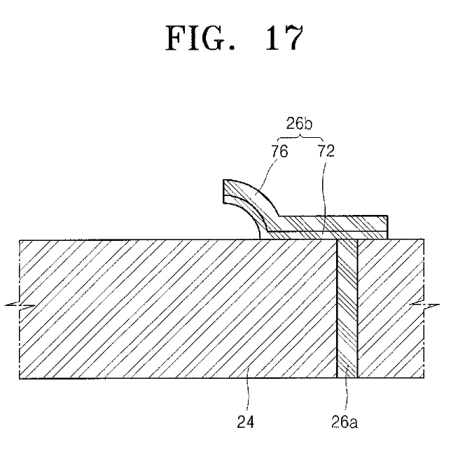

Referring to FIG. 17, after the photoresist pattern 74 is removed, the seed metal layer 72, except for a portion where the redistributed wiring layer 76 is formed, is removed. Next, the bump pattern 70 is removed. Finally, the redistributed wiring probe needle structure 26b including the seed metal layer 72 and the redistributed wiring layer 76 is formed. Although it is not illustrated in FIG. 17, the buffer member 54 may be formed in the redistributed wiring probe needle structure 26b in a molding method, as necessary.

As described above, the probe card of the embodiments of the present invention is formed of a wafer, that is, a wafer scale probe card. Accordingly, the wafer scale probe card exhibits a shortened manufacturing period and a low manufacturing cost by using the wafer-level process technique and the wafer-level packaging technique. Also, the probe card can remarkably reduce a test time by probing (testing) a plurality of unit chips on a wafer at once. Furthermore, the probe card of the embodiments of the present invention can be formed of a silicon wafer that is subject to a test so that the test can be performed according to a change in temperature, that is, a temperature history.

The probe card of the embodiments of the present invention includes a unique redistributed wiring probe needle structure to improve durability and reliability thereof. In the probe card, the redistributed wiring probe needle structure is of a twisted cage type. Accordingly, when a needle located at the leading end (the lower end) of the redistributed wiring probe needle structure contacts a pad of a unit chip of a wafer subject to a test, the needle rotates to cause friction with the pad. Thus, the contact ability between the probe needle and the pad is improved so that reliability of the test can be improved.

In the wafer scale type probe card of the embodiments of the present invention, the buffer member, for example, a silicon layer, which has a low thermal expansion coefficient so as to be stable against a high temperature and has a superior elasticity, can be provided around the probe needle locating at the leading end of the redistributed wiring probe needle structure of a twisted cage type, as necessary.

The present embodiments of the invention provide a wiring substrate connected to a tester and a probe card module including the above-described wafer probe card connected to the wiring substrate so that the unit chip of the wafer subject to a test can be tested. By doing so, the wafer scale probe card is formed of a silicon wafer and the buffer member is formed in and around the redistributed wiring probe needle structure so that the test according to the temperature history either at a high temperature or at a low temperature is made easy and also greatly improve the reliability of the probe card. Also, the probe card and the probe card module of the present invention can be used for a variety of wafer tests such as an EDS test and a burn-in test.

While this invention has been particularly shown and described with reference to exemplary embodiments thereof, it will be understood by those skilled in the art that various changes in form and details may be made therein without departing from the spirit and scope of the invention as defined by the appended claims.

What is claimed is:

1. A probe card comprising:
a probe card wafer;
a plurality of through via electrodes penetrating the probe card wafer; and
a plurality of wiring probe needle structures, each being connected to one of the through via electrodes protruding from a surface of the probe card wafer.

2. The probe card of claim 1, wherein each of the wiring probe needle structures comprises:
a metal ring connected to each of the through via electrodes;
a plurality of bars separated from one another and connected to the metal ring; and
a probe needle supportingly connected to the bars;
wherein each of the bars is positioned between the metal ring and the probe needle.

3. The probe card of claim 2, wherein the diameter of the metal ring is greater than that of the probe needle.

4. The probe card of claim 2, wherein a buffer member fills a space between the bars of each of the redistributed wiring probe needle structures.

5. The probe card of claim 1, wherein multilayered wiring layers are formed in the probe card wafer and electrically connected to the through via electrodes.

6. The probe card of claim 1, wherein the wiring probe needle structures are formed on a surface of the probe card wafer and connected to the through via electrodes, and connection terminals are formed on another surface of the probe card wafer and connected to a wiring substrate.

7. The probe card of claim 1, wherein the probe card wafer comprises:
a first probe card wafer where a plurality of first through via electrodes and the redistributed wiring probe needle structures are formed; and
a second probe card wafer where a plurality of second through via electrodes electrically connected to the first through via electrodes and the wiring probe needle structures on the first probe card wafer, and connection terminals connected to the second through via electrodes and the wiring substrate, are formed.

8. The probe card of claim 7, wherein the first probe card wafer is combined with the second probe card wafer.

9. A probe card module comprising:
a wiring substrate connected to a tester; and
a probe card electrically connected to the wiring substrate and testing a unit chip of a test wafer,
wherein the probe card comprises:
a probe card wafer corresponding to the test wafer;
a plurality of through via electrodes penetrating the probe card wafer; and
a plurality of wiring probe needle structures, each being connected to each of the through via electrodes protruding from the probe card wafer.

10. The probe card module of claim 9, wherein each of the wiring probe needle structures comprises:
a metal ring connected to each of the through via electrodes;
a plurality of bars separated from one another; and
a probe needle supportingly connected to the bars;
wherein each of the bars is positioned between the metal ring and the probe needle.

11. The probe card module of claim 10, wherein the plurality of bars are connected to the metal ring and, when the probe needle electrically contacts a pad of the unit chip of the test wafer, the probe needle rotates.

12. The probe card module of claim 9, wherein the wiring probe needle structures are formed on a surface of the probe card wafer and connected to the through via electrodes, and connection terminals are formed on another surface of the probe card wafer and connected to a wiring substrate.

13. The probe card module of claim 9, wherein the probe card wafer comprises:
a first probe card wafer where a plurality of first through via electrodes and the wiring probe needle structures are formed; and
a second probe card wafer where a plurality of second through via electrodes electrically connected to the first through via electrodes and the wiring probe needle structures on the first probe card wafer, and connection terminals connected to the second through via electrodes and the wiring substrate, are formed.

14. The probe card module of claim 9, wherein a buffer member fills the inside of each of the wiring probe needle structures.

15. A probe card module comprising:
a wiring substrate connected to a tester;
a guide member installed on a surface of the wiring substrate and having an open central portion; and
a probe card supported by the guide member, electrically connected to the wiring substrate, and testing a unit chip of a test wafer,
wherein the probe card comprises:
a probe card wafer corresponding to the test wafer;
a plurality of connection terminals installed on a surface of the probe card wafer and connected to the wiring substrate via a plurality of microsprings;
a plurality of through via electrodes penetrating the probe card wafer; and
a plurality of wiring probe needle structures, each being connected to each of the through via electrodes protruding from the probe card wafer.

16. The probe card module of claim 15, wherein each of the wiring probe needle structures rotates when each of the wiring probe needle structures electrically contacts a pad of the unit chip of the test wafer.

17. The probe card module of claim 15, wherein each of the redistributed wiring probe needle structures comprises:
a metal ring connected to each of the through via electrodes;
a plurality of bars separated from one another and connected to the metal ring; and
a probe needle supportingly connected to the bars, and
wherein each of the bars is positioned between the metal ring and the probe needle.

18. The probe card module of claim 17, wherein the probe needle is rotated by the bars connected to the metal ring when the probe needle electrically contacts a pad of the unit chip of the test wafer.

19. The probe card module of claim 15, wherein the probe card wafer comprises:
a first probe card wafer where a plurality of first through via electrodes and the wiring probe needle structures are formed; and
a second probe card wafer where a plurality of second through via electrodes electrically connected to the first through via electrodes and the wiring probe needle structures on the first probe card wafer, and connection terminals connected to the second through via electrodes and the wiring substrate, are formed, and
wherein the first and second probe cards are combined with each other.

20. The probe card module of claim 15, wherein a buffer member fills the inside of each of the wiring probe needle structures.
